(19) United States
(12) Patent Application Publication
(10) Pub. No.: US 2026/0136771 A1
(43) Pub. Date: May 14, 2026

(54) DISPLAY DEVICE AND MANUFACTURING METHOD OF DISPLAY DEVICE

(71) Applicant: Magnolia White Corporation, Tokyo (JP)

(72) Inventors: Hiraaki KOKAME, Tokyo (JP); Akinori KAMIYA, Tokyo (JP)

(73) Assignee: Magnolia White Corporation, Tokyo (JP)

(21) Appl. No.: 19/389,061

(22) Filed: Nov. 14, 2025

(30) Foreign Application Priority Data
Nov. 14, 2024 (JP) 2024-198987

(51) Int. Cl. H10K 59/122; H10K 59/12

(52) U.S. Cl. CPC H10K 59/122; H10K 59/1201

(57) ABSTRACT

According to one embodiment, a display device includes a substrate having a display area and a surrounding area, a first lower electrode, a rib layer including a first surface located on a side opposite to the substrate and a pixel aperture overlapping the first lower electrode, a partition having a first lower portion and a first upper portion, an organic layer, an upper electrode, and a cap layer, and a first sealing layer formed of an inorganic material, covering the cap layer, and having a second surface located on a side opposite to the substrate and having a surface roughness greater that of the first surface.

### CROSS-REFERENCE TO RELATED APPLICATIONS

This application is based upon and claims the benefit of priority from Japanese Patent Application No. 2024-198987, filed Nov. 14, 2024, the entire contents of which are incorporated herein by reference.

### FIELD

Embodiments described herein relate generally to a display device and a manufacturing method of a display device.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device DSP according to the present embodiment.

FIG. 2 is a schematic plan view showing an example of the layout of subpixels.

FIG. 3 is a schematic cross-sectional view of the display device along III-III line of FIG. 2.

FIG. 4 is a schematic plan view in which the area surrounded by the frame IV of FIG. 3 is enlarged.

FIG. 5 is a schematic plan view showing some elements of the display device.

FIG. 6 is a schematic cross-sectional view showing a configuration around a slit.

FIG. 7 is a schematic plan view showing some elements of the display device.

FIG. 8 is a schematic plan view in which the area surrounded by the frame VIII of FIG. 7 is enlarged.

FIG. 9 is a schematic cross-sectional view of the display device along the IX-IX line of FIG. 8.

FIG. 10 is a schematic cross-sectional view of the display device in a surrounding area.

FIG. 11 is a schematic plan view of a mother substrate according to the present embodiment.

FIG. 12 is a schematic plan view of a panel portion.

FIG. 13A is a schematic cross-sectional view showing a manufacturing process of the display device.

FIG. 13B is a schematic cross-sectional view showing a process following FIG. 13A.

FIG. 13C is a schematic cross-sectional view showing a process following FIG. 13B.

FIG. 13D is a schematic cross-sectional view showing a process following FIG. 13C.

FIG. 13E is a schematic cross-sectional view showing a process following FIG. 13D.

FIG. 13F is a schematic cross-sectional view showing a process following FIG. 13E.

FIG. 13G is a schematic cross-sectional view showing a process following FIG. 13F.

FIG. 13H is a schematic cross-sectional view showing a process following FIG. 13G.

FIG. 13I is a schematic cross-sectional view showing a process following FIG. 13H.

FIG. 13J is a schematic cross-sectional view showing a process following FIG. 13I.

FIG. 14A is a schematic cross-sectional view showing a manufacturing process of the display device.

FIG. 14B is a schematic cross-sectional view showing a process following FIG. 14A.

FIG. 14C is a schematic cross-sectional view showing a process following FIG. 14B.

FIG. 14D is a schematic cross-sectional view showing a process following FIG. 14C.

FIG. 14E is a schematic cross-sectional view showing a process following FIG. 14D.

FIG. 15A is a schematic cross-sectional view showing a manufacturing process of a display device according to a comparative example.

FIG. 15B is a schematic cross-sectional view showing a process following FIG. 15A.

FIG. 16 is a schematic cross-sectional view showing the manufacturing process of a display device according to a comparative example.

### DETAILED DESCRIPTION

In general, according to one embodiment, a display device includes a substrate having a display area for displaying an image and a surrounding area outside the display area, a first lower electrode provided above the substrate in the display area, a rib layer formed of an inorganic material and including a first surface located on a side opposite to the substrate and a pixel aperture overlapping the first lower electrode, a partition having a first lower portion provided on the first surface and having conductivity and a first upper portion provided on the first lower portion and protruding relative to a side surface of the first lower portion, an organic layer contacting the first lower electrode through the pixel aperture, an upper electrode covering the organic layer and contacting the first lower electrode, and a cap layer covering the upper electrode, and a first sealing layer formed of an inorganic material, covering the cap layer, and having a second surface located on a side opposite to the substrate and having a surface roughness greater that of the first surface.

In general, according to one embodiment, a display device manufacturing method includes steps of forming a lower electrode in a display area for displaying images, forming a rib layer having a pixel aperture overlapping the lower electrode and formed of an inorganic material, forming a partition having a first lower portion provided on the rib layer and having conductivity and a first upper portion provided on the first lower portion and protruding relative to a side surface of the first lower portion, forming across the display area and a surrounding area outside the display area an organic layer contacting the lower electrode through the pixel aperture, an upper electrode covering the organic layer and contacting the first lower portion, a cap layer covering the upper electrode, and a first sealing layer covering the cap layer, and performing a surface treatment on an upper surface of the first sealing layer to roughen the upper surface.

The present embodiment can provide a display device capable of improving yields and a manufacturing method of the display device.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction along the X-axis is referred to as an X-direction (the first direction,) a direction along the Y-axis is referred to as a Y-direction (the second direction), and a direction along the Z-axis is referred to as a Z-direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

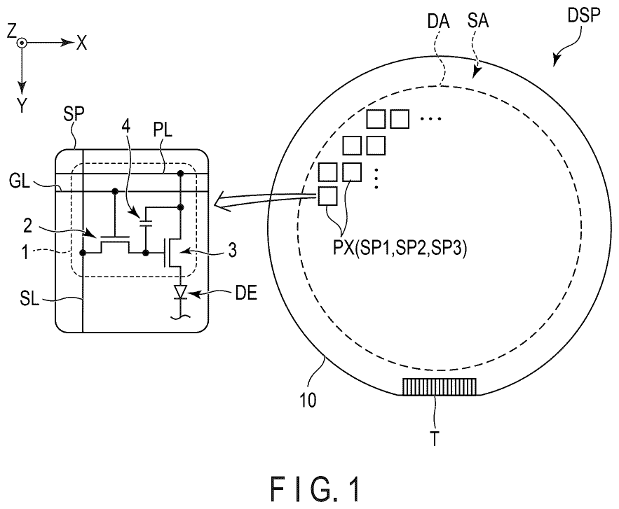

FIG. 1 is a view showing a configuration example of a display device DSP according to the present embodiment. The display device DSP comprises an insulating substrate 10. The substrate 10 has a display area DA for displaying images and a surrounding area SA outside the display area DA. The substrate 10 may be glass or a resinous film having flexibility.

In the present embodiment, the substrate 10 has a circular shape in plan view. The shape of the substrate 10 in a plan view is not limited to the circular shape and may be another shape such as a rectangular shape, a square shape, or an elliptic shape.

The display area DA comprises a plurality of pixels PX arranged in a matrix in the X direction and the Y direction. Each pixel PX includes a plurality of subpixels SP which display different colors. The present embodiment assumes a case where each pixel PX includes a green subpixel SP1, a blue subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the X direction, and the signal lines S extend in the Y direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

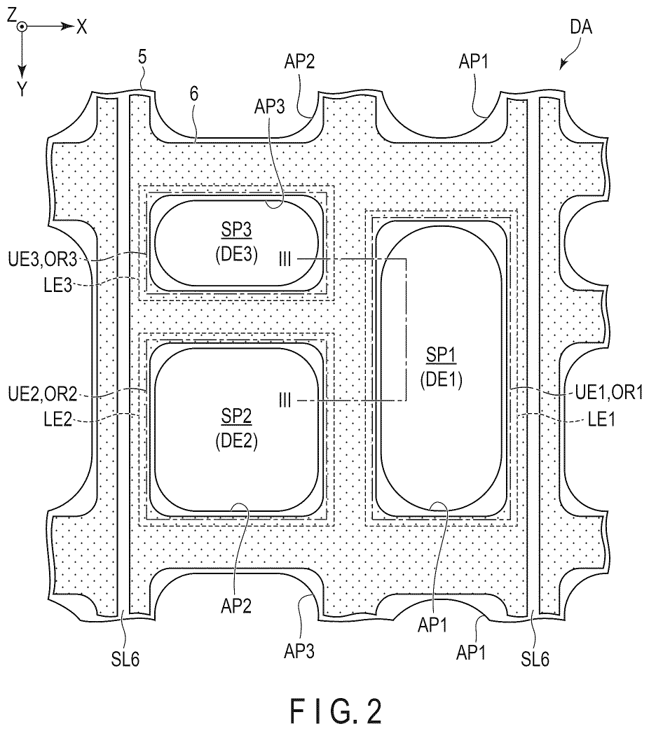

FIG. 2 is a schematic plan view showing an example of the layout of the subpixels SP1, SP2, and SP3. In the example of FIG. 2, the subpixels SP2 and SP3 are arranged with the subpixel SP1 in the X direction. Further, the subpixels SP2 and SP3 are arranged in the Y direction.

When the subpixels SP1, SP2 and SP3 are arranged in this layout, in the display area DA, a column in which the subpixels SP2 and SP3 are alternately arranged in the Y direction and a column in which the plurality of subpixels SP1 are repeatedly arranged in the Y direction are formed. These columns are alternately arranged in the X direction. The layout of the subpixels SP1, SP2, and SP3 is not limited to the example of FIG. 2.

A rib layer 5 is provided in the display area DA. The rib layer 5 has pixel apertures AP1, AP2, and AP3 in the subpixels SP1, SP2, and SP3, respectively. In the example of FIG. 2, the pixel aperture AP1 is greater than the pixel aperture AP2, and the pixel aperture AP2 is greater than the pixel aperture AP3. Thus, among the subpixels SP1, SP2, and SP3, the aperture ratio of the subpixel SP1 is the greatest, and the aperture ratio of the subpixel SP3 is the least. The size and the shape of each of the pixel apertures AP1, AP2, and AP3 are not limited to the illustrated example.

The subpixel SP1 comprises a lower electrode LE1 (the first lower electrode), an upper electrode UE1, and an organic layer OR1, which overlap the pixel aperture AP1. The subpixel SP2 comprises a lower electrode LE2 (the second lower electrode), an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided in the display area DA. The partition 6 is located above the rib layer 5 to entirely overlap the rib layer 5. In the example of FIG. 2, the partition 6 has a planar shape similar to that of the rib layer 5. That is, the partition 6 includes an aperture in each of the subpixels SP1, SP2, and SP3. From another viewpoint, each of the rib layer 5 and the partition 6 has a grating shape in plan view and surrounds each of the display elements DE1, DE2, and DE3. Further, the partition 6 surrounds the pixel apertures AP1, AP2, and AP3. The partition 6 functions as lines which apply common voltage to the upper electrodes UE1, UE2, and UE3.

As described in detail later, the partition 6 has a plurality of slits SL6. In the example of FIG. 2, each of the slits SL6 extends in the Y-direction. For example, the subpixels SP1, SP2, and SP3 constituting one pixel PX are provided between two slits SL6 adjacent to each other in the X-direction.

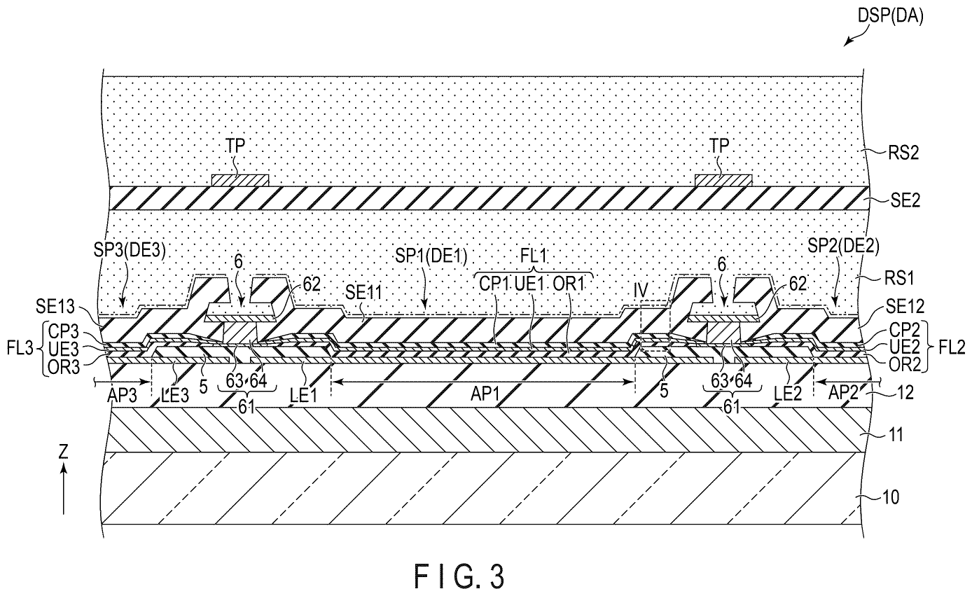

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered with the rib layer 5. Although not shown in the section in FIG. 3, the lower electrodes LE1, LE2, and LE3 are connected to the respective pixel circuits 1 (drain electrode of the drive transistor 3 shown in FIG. 1) of the circuit layer 11 through respective contact holes provided in the organic insulating layer 12. The rib layer 5 has a first surface S1 located on a side opposite to the substrate 10 in the Z-direction.

The partition 6 includes a lower portion 61 (the first lower portion) having conductivity and provided on the first surface S1 and an upper portion 62 (the first upper portion) provided on the lower portion 61. The upper portion 62 has a width greater than that of the lower portion 61. This configuration allows the both end portions of the upper portion 62 to protrude relative to the side surfaces of the lower portion 61. This shape of the partition 6 is called an overhang shape.

In the example of FIG. 3, the lower portion 61 has a bottom layer 63 provided on the first surface S1 and a stem layer 64 provided on the bottom layer 63. For example, the bottom layer 63 is formed to be thinner than the stem layer 64. In the example of FIG. 3, the both end portions of the bottom layer 63 protrude relative to the side surfaces of the stem layer 64. Further, the both end portions of the bottom layer 63 are located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13 (the first sealing layers), which respectively cover the stacked films FL1, FL2, and FL3 are respectively provided in the subpixels SP1, SP2, and SP3. The sealing layer SE11 (the first portion) continuously covers the display element DE1 and the partition 6 around the display element DE1. The sealing layer SE12 (the second portion) continuously covers the display element DE2 and the partition 6 around the display element DE2. The sealing layer SE13 continuously covers the display element DE3 and the partition 6 around the display element DE3. The sealing layers SE11, SE12, and SE13 have a second surface S2 located on a side opposite to the substrate 10 in the Z-direction. The surface treatment to be described later is performed on the second surface S2. In the figure, the area on which the surface treatment is performed of the second surface S2 is indicated by a dashed-two dotted line.

In the example of FIG. 3, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. Two of the sealing layers SE11, SE12, and SE13 may contact each other above the partition 6.

For example, a gap is formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1 (the first resin layer). More specifically, the second surface S2 is covered with the resin layer RS1. The resin layer RS1 is covered with a sealing layer SE2 (the second sealing layer). The sealing layer SE2 is covered with a resin layer RS2 (the second resin layer). The resin layers RS1 and RS2 and the sealing layer SE2 are continuously provided in at least the entire display area DA and partly extend in the surrounding area SA as well.

In the example of FIG. 3, a touch panel electrode TP for detecting touch operations by a user is provided on the sealing layer SE2. For example, the touch panel electrode TP is formed of a metal material and has the same shape as that of the partition 6 in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer and a pair of conductive oxide layers covering the upper and lower surfaces of the reflective layer. The reflective layer is formed of, for example, a metallic material having excellent light-reflecting properties, such as silver. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum (Mo), titanium (Ti), titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the upper portion 62 of the partition 6 includes a stacked layer structure comprising a lower layer formed of a metal material and an upper layer formed of a conductive oxide. For the metal material forming the lower layer, for example, titanium, a titanium nitride, molybdenum, tungsten, a molybdenum-tungsten alloy, or a molybdenum-niobium alloy may be used. For a conductive oxide forming the top layer, for example, ITO or IZO may be used. The upper portion 62 may comprise a single-layer structure of a metal material. The upper portion 62 may further include a layer formed of an insulating material.

Common voltage is applied to the partition 6. This common voltage is applied to each of the upper electrodes UE1, UE2, and UE3 in contact with the side surfaces of the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light of the green wavelength range. When a potential difference is formed between the lower electrode LE2 and the upper electrode UE2, the light emitting layer of the organic layer OR2 emits light in the blue wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise a color filter that converts the light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

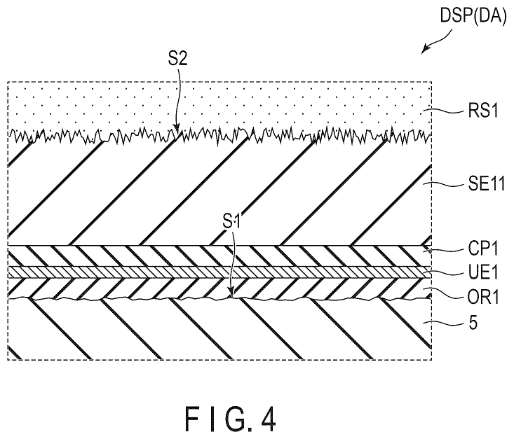

FIG. 4 is a schematic plan view in which the area surrounded by the frame IV of FIG. 3 is enlarged.

Uneven parts finer than those of the first surface S1 are formed on the second surface S2. That is, the surface roughness of the second surface S2 is greater than that of the first surface S1. From another view point, the number of the uneven parts provided on the second surface S2 is greater than that of the first surface S1.

The surface roughness here may apply metrics such as arithmetic mean roughness (Ra), maximum height roughness (Rz, Rmax), and root mean square roughness (Rq) as defined in JISB0601: 2013. The surface roughness of each of the first surface S1 and the second surface S2 can be measured, for example, by analyzing a cross-section of the display device DSP using a non-contact surface roughness measuring instrument.

The same configuration as the sealing layer SE11 can also be applied to the sealing layers SE12 and SE13. That is, the surface roughness of each of the second surface S2 of each of the sealing layers SE12 and SE13 is greater than that of the first surface S1.

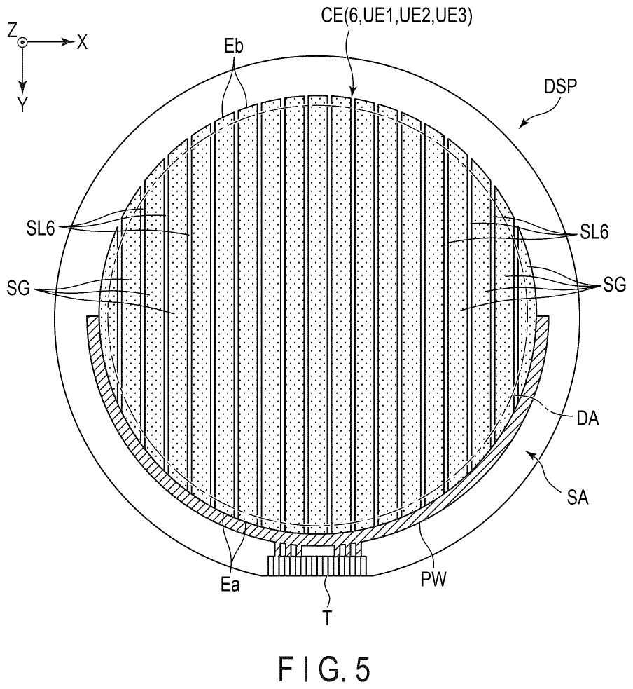

FIG. 5 is a schematic plan view showing some elements of the display device DSP. The partition 6 and the upper electrodes UE1, UE2, and UE3 constitute a common electrode CE, which applies common voltage to the display elements DE1, DE2, and DE3. For example, the common electrode CE has a circular shape and entirely overlaps the display area DA.

The common electrode CE has the plurality of slits SL6. At least one end of each of the slits SL6 reaches the outer edge of the common electrode CE (the outline in plan view). In the example of FIG. 5, the both ends of the slit SL6 reach the outer edge of the common electrode CE. This causes the common electrode CE to be split into a plurality of segments SG spaced apart from each other via the slits SL6.

In the example of FIG. 5, each slit SL6 extends in the Y-direction. As another example, each slit SL6 may extend in a direction parallel to the X-direction. The number of the slits SL6 provided in the common electrode CE is not particularly limited.

The intervals of the slits SL6 in the X-direction are, for example, constant. In this case, the widths of the segments SG in the X-direction are also constant. As another example, the interval of the slits SL6 and the widths of the segments SG may not be constant.

Each of the segments SG has end portions Ea and Eb in the extending direction of the slit SL6 (the Y-direction in the present embodiment). The end portion Ea is connected to a power supply line PW provided in the surrounding area SA. The power supply line PW is connected to the terminal portion T. Common voltage is applied to each of the segments SG from the terminal portion T via the power supply line PW. In the example of FIG. 5, the end portions Eb of the segments SG are spaced apart from each other by the slits SL6. That is, these end portions Eb are not connected to each other by a conductive member such as the power supply line PW.

The slits SL6 divide the common electrode CE into the plurality of segments SG. This configuration suppresses occurrence of a large eddy current in the common electrode CE. This configuration can suppress degradation in communication sensitivity in the near-field communication (NFC).

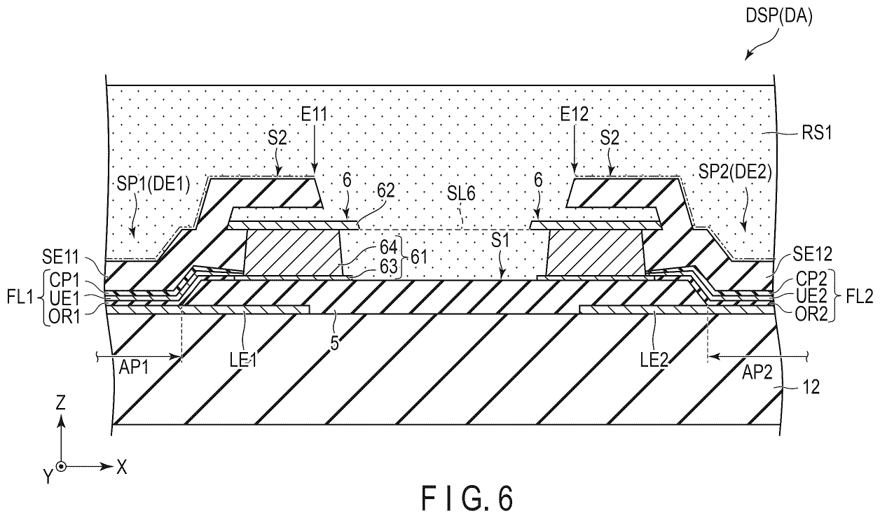

FIG. 6 is a schematic cross-sectional view showing a configuration around the slits SL6. FIG. 6 omits the elements located under the organic insulating layer 12 and the elements located above the resin layer RS1.

The slits SL6 are provided between the lower electrodes LE1 and LE2. The sealing layers SE11 and SE12 are spaced apart from each other directly above the slits SL6. The resin layer RS1 fills the slits SL6 and contacts the rib layer 5.

Electronic devices on which the display device DSP is mounted may comprise an optical sensor such as an illumination sensor, which detects external light. For example, this optical sensor is provided on the rear surface side of the display device DSP (the substrate 10 side). If the slit SL6 is provided in the partition 6, the external light passes through the slits SL6 and reaches the optical sensor.

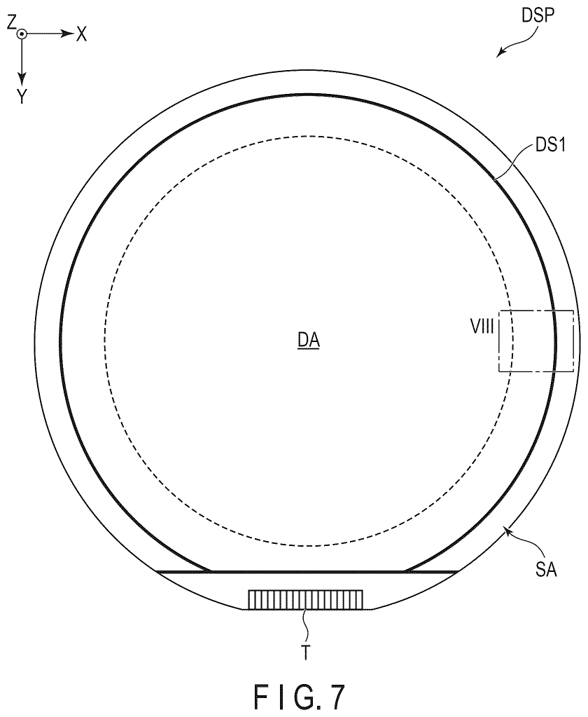

FIG. 7 is a schematic plan view showing some elements of the display device DSP. A dam portion DS1 is provided in the surrounding area SA. The dam portion DS1 is located between the display area DA and the terminal portion T and surrounds the display area DA. The dam portion DS1 extends in the X-direction in the vicinity of terminal portion T. The dam portion DS1 is constituted by a plurality of dams formed in a convex shape.

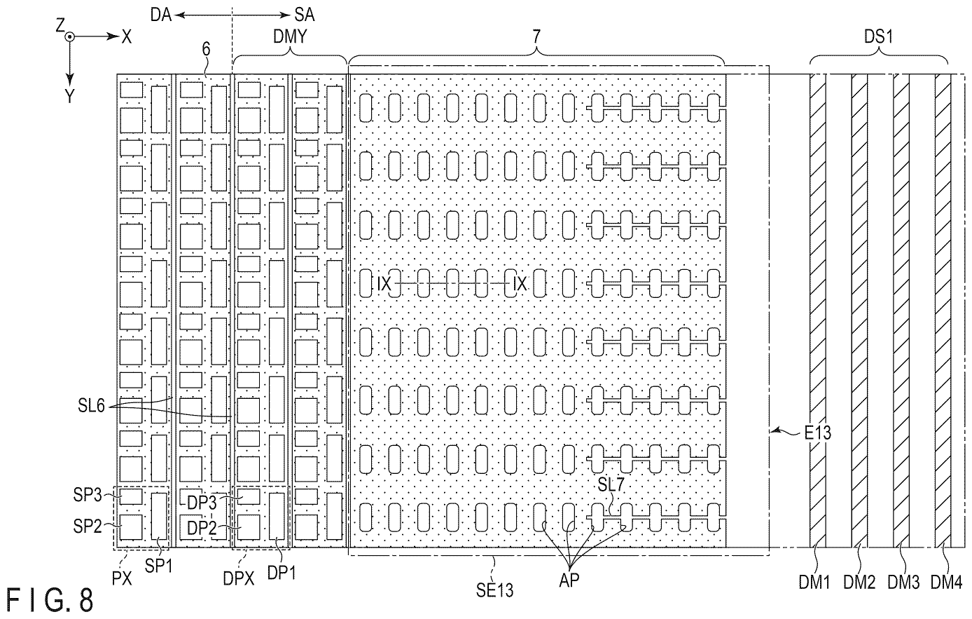

FIG. 8 is a schematic plan view in which the area surrounded by the frame VIII of FIG. 7 is enlarged. In addition to the dam portion DS1, the dummy pixel area DMY and a surrounding partition 7 are provided in the surrounding area SA. The dummy pixel area DMY surrounds the display area DA and is adjacent to the display area DA. The surrounding partition 7 is provided between the display area DA and the dam portion DS1 and surrounds the dummy pixel area DMY and the display area DA. The dam portion DS1 surrounds the surrounding partition 7, the dummy pixel area DMY, and the display area DA.

A plurality of dummy pixels DPX are provided in the dummy pixel area DMY. For example, each of the dummy pixels DPX includes dummy subpixels DP1, DP2, and DP3. Each of the dummy subpixels DP1, DP2, and DP3 has the configuration similar to that of the respective subpixels SP1, SP2, and SP3 shown in FIG. 2. That is, the dummy subpixel DP1 comprises the lower electrode LE1, the organic layer OR1, the upper electrode UE1, and the sealing layer SE11. The dummy subpixel DP2 comprises the lower electrode LE2, the organic layer OR2, the upper electrode UE2, and the sealing layer SE12. The dummy subpixel DP3 comprises the lower electrode LE3, the organic layer OR3, the upper electrode UE3, and the sealing layer SE13.

However, the dummy subpixels DP1, DP2, and DP3 are configured not to emit light. This configuration may be realized by, for example, disconnecting part of the pixel circuit 1 in each of the dummy subpixels DP1, DP2, and DP3. The pixel apertures AP1, AP2, and AP3 may be omitted in the dummy subpixels DP1, DP2, and DP3, respectively. Thus, the rib layer 5 is interposed between the organic layers OR1, OR2, and OR3 and the lower electrodes LE1, LE2, and LE3. Thus, a voltage for making the organic layers OR1, OR2, and OR3 to emit light is not supplied to these organic layers OR.

Part of the partition 6 is located in the dummy pixel area DMY and surrounds each of the plurality of dummy pixels DPX. More specifically, the partition 6 surrounds each of the dummy subpixels DP1, DP2 and DP3. The shapes and layout of the apertures of the partition 6 in the respective dummy subpixels DP1, DP2, and DP3 are the same as those of the apertures of the partition 6 in the respective subpixels SP1, SP2, and SP3. The slits SL6 are provided in the dummy pixel area DMY as well.

The surrounding partition 7 has a plurality of apertures AP provided in the matrix. From another viewpoint, the surrounding partition 7 is formed into a grating shape in plan view. In the example shown in FIG. 8, the plurality of apertures AP arranged in the X-direction in the dam portion DS1 side are continuous via slits SL7. For example, the surrounding partition 7 is covered with the sealing layer SE13. The surrounding partition 7 may be covered with the sealing layers SE11 and SE12 instead of the sealing layer SE13.

The sealing layer SE13 has an end portion E13 located between the display area DA and the dam portion DS1. In the example shown in FIG. 8, the end portion E13 is located between the surrounding partition 7 and the dam portion DS1.

The dam portion DS1 comprises a dam DM1 surrounding the surrounding partition 7, a dam DM2 surrounding the dam DM1, a dam DM3 surrounding the dam DM2, and a dam DM4 surrounding the dam DM3. The number of the dams that the dam portion DS1 comprises is not limited to four.

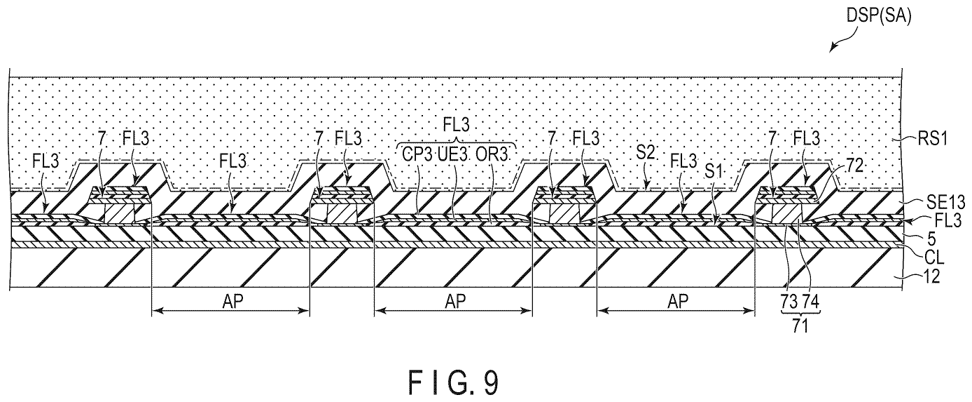

FIG. 9 is a schematic cross-sectional view of the display device DSP along the IX-IX line of FIG. 8. FIG. 9 omits the elements located under the organic insulating layer 12 and the elements located above the resin layer RS1.

A conductive layer CL is provided between the organic insulating layer 12 and the rib layer 5 in the surrounding area SA. For example, the conductive layer CL is formed of the same material and process as those of the lower electrodes LE1, LE2, and LE3 described above.

The surrounding partition 7 is provided on the rib layer 5 in the surrounding area SA. The surrounding partition 7 includes a lower portion 71 (the second lower portion) provided on the first surface S1 and an upper portion 72 (the second upper portion) provided on the lower portion 71. The upper portion 72 has a width greater than that of the lower portion 71. This configuration allows both end portions of the upper portion 72 to protrude relative to the side surfaces of the lower portion 71.

In the example of FIG. 9, the lower portion 71 has a bottom layer 73 provided on the rib layer 5 and a stem layer 74 provided on the bottom layer 73. For example, the bottom layer 73 is thinner than the stem layer 74. In the example of FIG. 9, the both end portions of the bottom layer 73 protrude relative to the side surfaces of the stem layer 74. Further, the both end portions of the bottom layer 73 are located between the end portion of the upper portion 72 and the side surface of the stem layer 74 in plan view. The upper portion 72 is provided on the stem layer 74.

The bottom layer 73 is formed of the same material as the bottom layer 63 shown in FIG. 3. The stem layer 74 is formed of the same material as the stem layer 64 shown in FIG. 3. The upper portion 72 is formed of the same material as the upper portion 62 shown in FIG. 3. The lower portion 71 may have the conductivity in the same manner as the lower portion 61 shown in FIG. 3. Alternatively, the lower portion 71 may not have the conductivity.

In the surrounding area SA, the stacked film FL3 including the organic layer OR3, the upper electrode UE3, and the cap layer CP3 is provided on the rib layer 5 and the upper portion 72. The stacked film FL3 and the plurality of apertures AP are covered with the sealing layer SE13. In the example shown in FIG. 9, the sealing layer SE13 contacts the cap layer CP3 via the aperture AP. The sealing layer SE13 is covered with the resin layer RS1.

In the same manner as the display area DA, the surface treatment is performed on the second surface S2 of the sealing layer SE13 in the surrounding area SA as well. That is, in the surrounding area SA as well, the surface roughness of the second surface S2 is greater than that of the first surface S1.

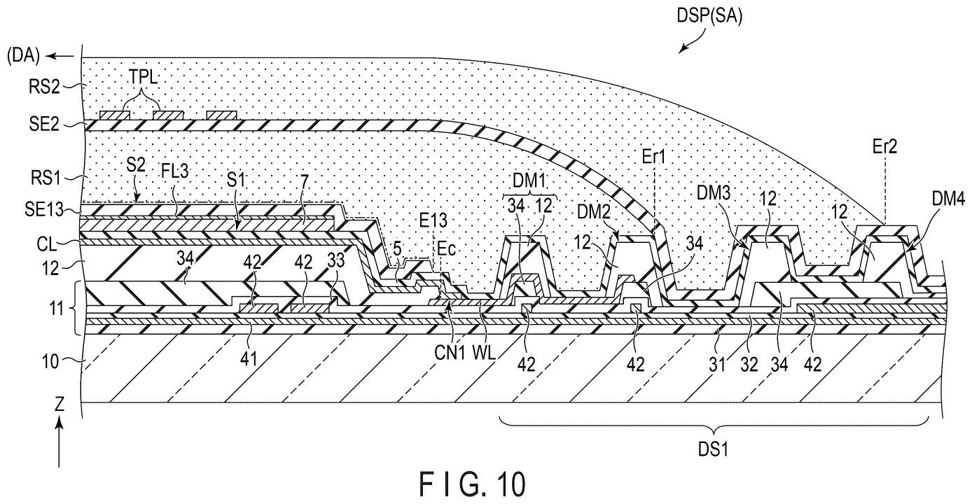

FIG. 10 is a schematic cross-sectional view of the display device DSP in the surrounding area SA.

The circuit layer 11 shown in FIG. 3 has inorganic insulating layers 31, 32, and 33 formed of an inorganic insulating material, an organic insulating layer 34 formed of an organic insulating material, and metal layers 41 and 42. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The organic insulating layer 34 is covered with the organic insulating layer 12.

Each of the dams DM1, DM2, DM3, and DM4 protrudes toward the upper side of the substrate 10. In the example of FIG. 10, the dam DM1 is formed of the organic insulating layers 12 and 34. Similarly, the dam portions DM2, DM3, and DM4 are formed of the organic insulating layers 12 and 34. That is, in the present embodiment, the dams DM1, DM2, DM3, and DM4 are formed of the same materials as the organic insulating layers 12 and 34 in the same layers as the organic insulating layers 12 and 34.

A wire WL is provided below the dams DM1 and DM2. For example, the wire WL constitutes the power supply line PW shown in FIG. 5. Part of the wire WL is located between the organic insulating layers 12 and 34 in each of the dams DM1 and DM2.

The conductive layer CL is located on the display area DA side (the left side in the figure) relative to the dam DM1 and covers the organic insulating layer 12. The conductive layer CL contacts the wire WL in the contact portions CN1. The contact portion CN1 is located between an end portion Ec of the organic insulating layer 12 and the dam portion DM1 in plan view. The rib layer 5 continuously covers the conductive layer CL and the dams DM1, DM2, DM3, and DM4.

The end portion E13 of the sealing layer SE13 is located between the surrounding partition 7 and the dam DM1. That is, the dams DM1, DM2, DM3, and DM4 are not covered with the sealing layer SE13. Further, parts of the rib layer 5 located directly above the dams DM1, DM2, DM3, and DM4 are exposed from the sealing layer SE13. In the example shown in FIG. 10, the end portion E13 is located between the surrounding partition 7 and the end portion Ec.

The resin layer RS1, the sealing layer SE2, and the resin layer RS2 shown in FIG. 3 are provided above the sealing layer SE13. Further, a touch panel line TPL connected to the touch panel electrode TP shown in FIG. 3 is provided on the sealing layer SE2. For example, the touch panel line TPL is formed of the same material as the touch panel electrode TP.

In the manufacturing of the display device DSP, the dams DM1, DM2, DM3, and DM4 function to dam up the resin layers RS1 and RS2 before curing. In the example shown in FIG. 10, an end portion Er1 of the resin layer RS1 is located above the dam portion DM2. That is, the resin layer RS1 partly covers the dams DM1 and DM2. The position of the end portion Er1 is not limited to this example.

The sealing layer SE2 covers the end portion Er1 of the resin layer RS1 and the dams DM3 and DM4. The sealing layer SE2 contacts the rib layer 5 in an area located outside the end portion Er1 (the right side in the figure). In the example shown in FIG. 10, an end portion Er2 of the resin layer RS2 is located above the dam portion DM4. That is, the resin layer RS2 covers parts of the dams DM3 and DM4. The position of the end portion Er2 is not limited to this example.

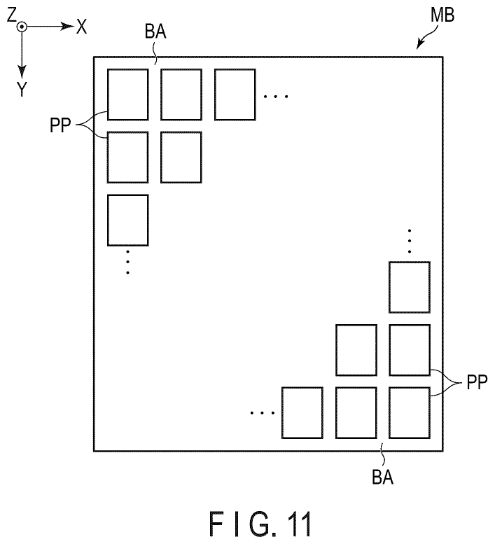

FIG. 11 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel portions PP provided in a matrix and a margin area BA around these panel portions PP. In the example of FIG. 11, the panel portions PP are arranged in the X-direction and the Y-direction via the margin area BA. The layout of the panel portions PP in the mother substrate MB is not limited to this example. As another example, some of the panel portions PP may be arranged without interposing the margin area BA therebetween.

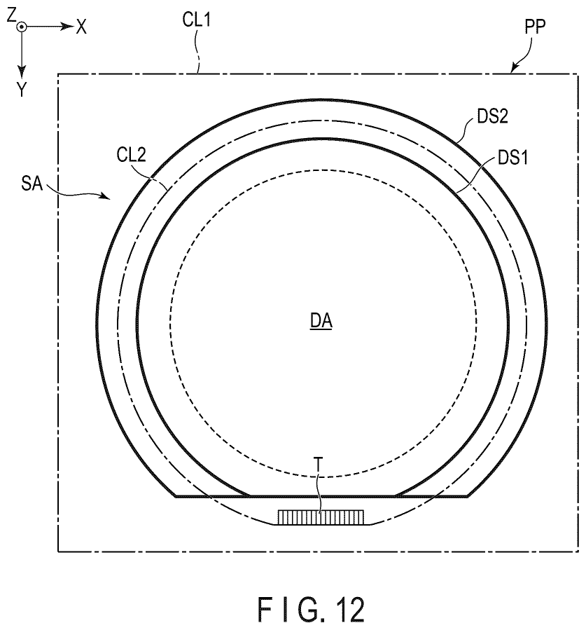

FIG. 12 is a schematic plan view of the panel portion PP. The outer shape of the panel portion PP corresponds to a cut line CL1 for cutting out each panel portion PP from the mother substrate MB.

Each panel portion PP has the display area DA and the surrounding area SA. The surrounding area SA in the panel portion PP corresponds to the area between the display area DA and the cut line CL1.

The surrounding area SA further has a cut line CL2, which is the outer shape of the substrate 10 of the display device DSP. In the manufacturing of the display device DSP, the panel portion PP is cut out from the mother substrate MB along the cut line CL1. Further, the display device DSP is cut out from the panel portion PP along the cut line CL2.

In addition to the dam portion DS1, the panel portion PP comprises a dam portion DS2. The dam portion DS2 functions to dam up the resin layer RS2 before curing. For example, the dam structure DS2 has a plurality of dams formed of the organic insulating layers 12 and 34 in the same manner as the dams DM1, DM2, DM3, and DM4.

The dam portion DS1 is located between the cut line CL2 and the display area DA and surrounds the display area DA. The dam structure DS2 is located between the cut lines CL1 and CL2 and surrounds the cut line CL2. In the example of FIG. 12, the dam portions DS1 and DS2 merge in the vicinity of the terminal portion T. This merged portion passes between the terminal portion T and the display area DA.

The most part of the cut line CL2 is located between the dam portions DS1 and DS2. In the example of FIG. 12, the cut line CL2 is located on the outside of the dam portions DS1 and DS2 in the vicinity of the terminal portion T. That is, the cut line CL2 traverses the dam portion DS2 in the vicinity of the terminal portion T.

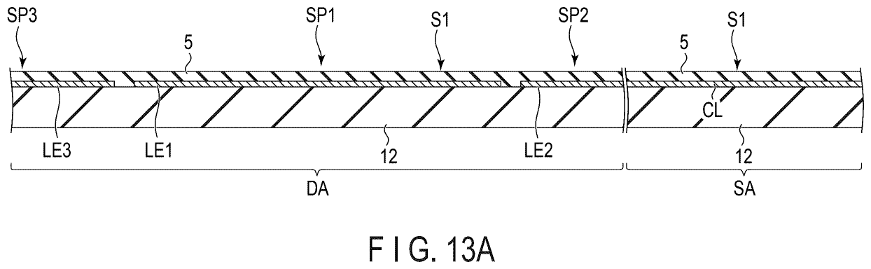

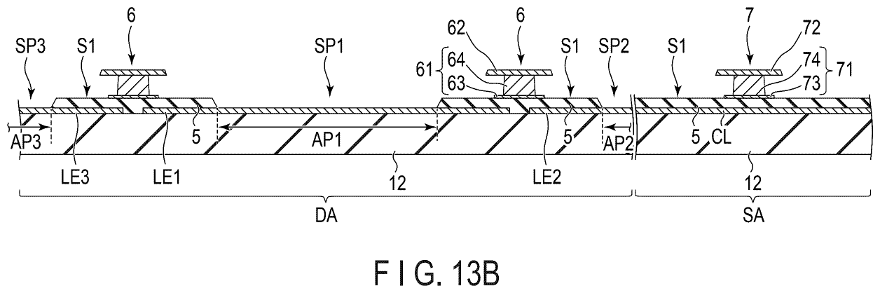

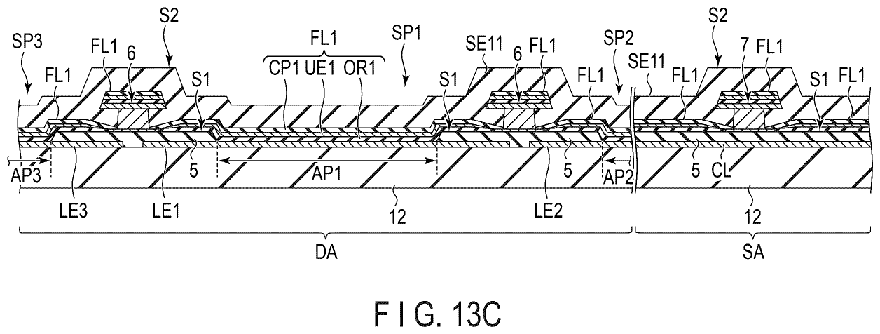

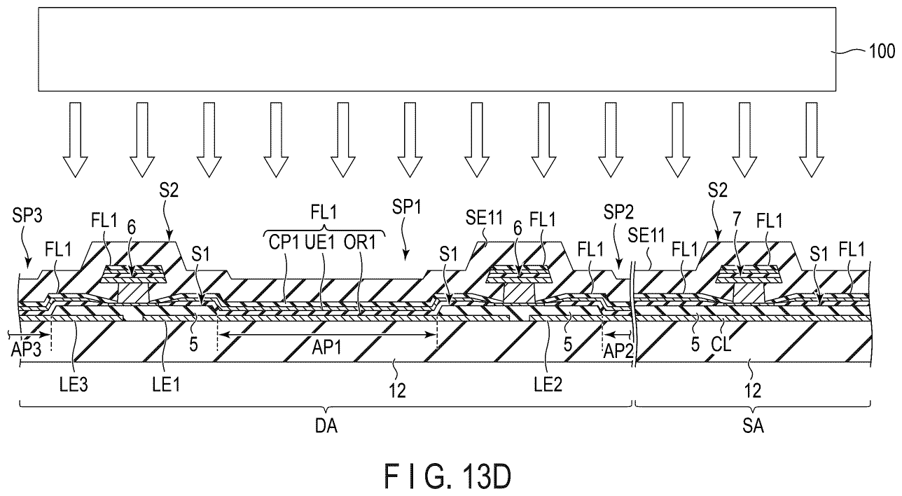

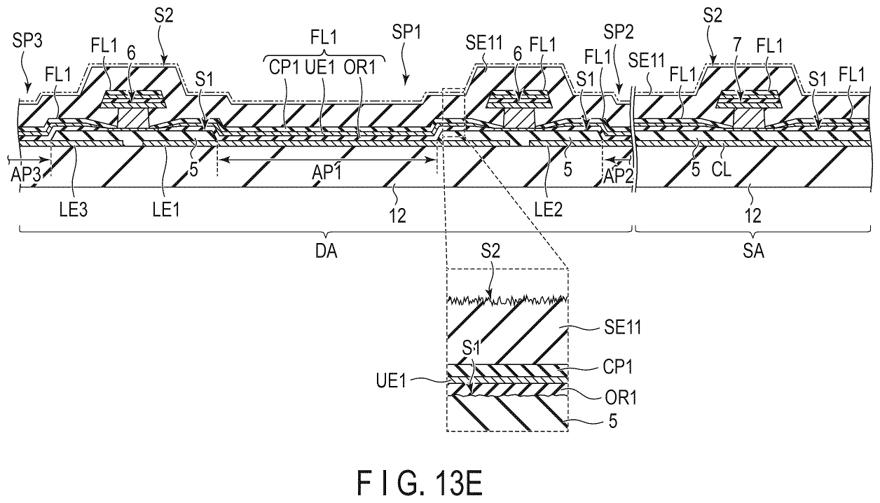

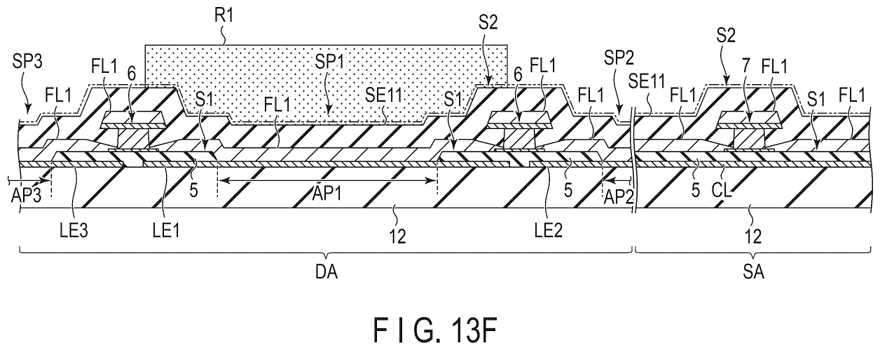

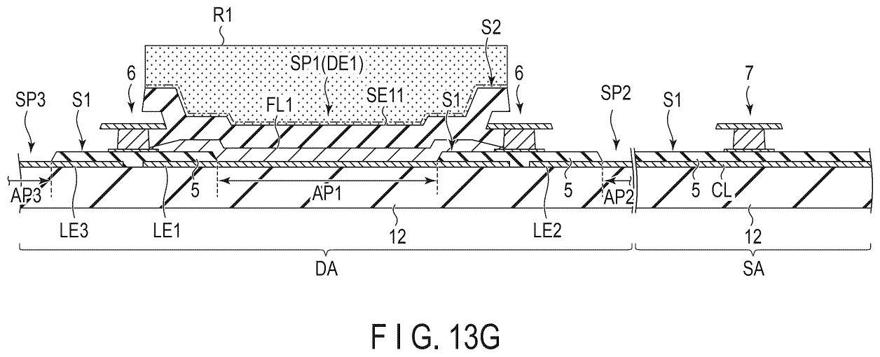

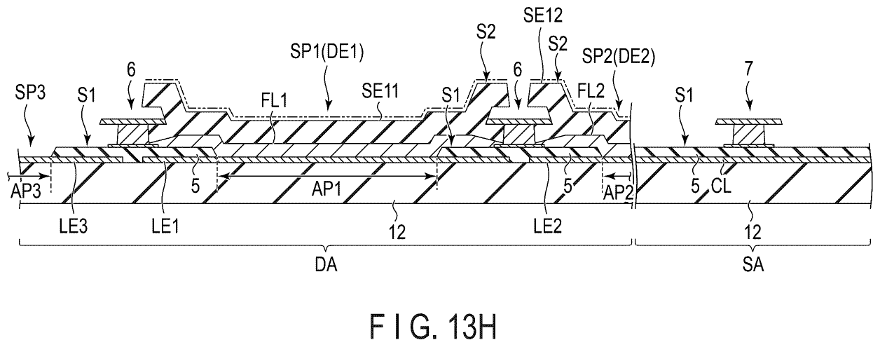

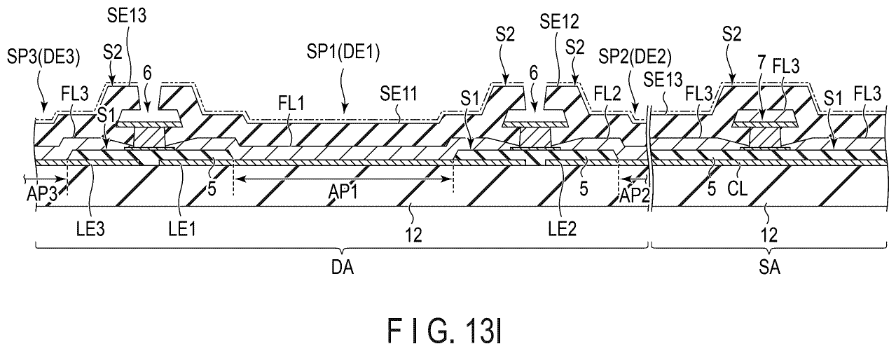

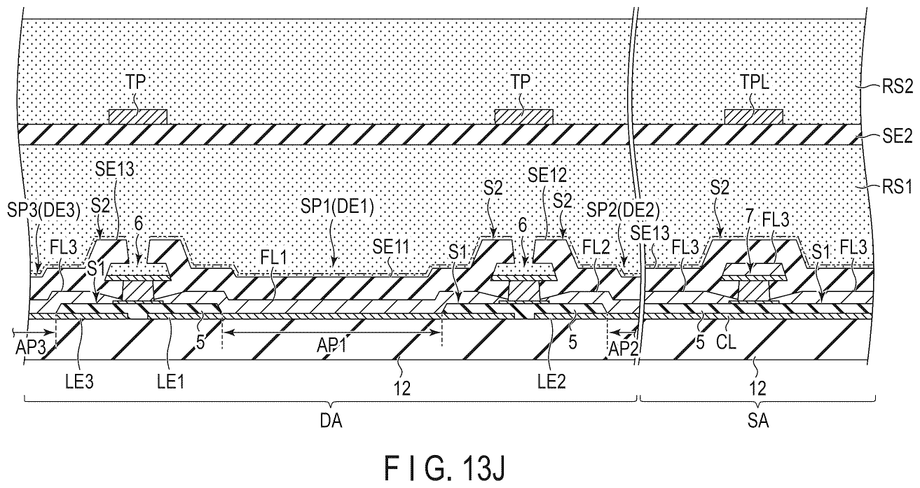

The following will describe an example of the manufacturing method of the display device DSP. FIG. 13A to FIG. 13J are schematic cross-sectional views showing the manufacturing process of the display device DSP. FIG. 13A to FIG. 13J omit the illustration of the elements below the organic insulating layer 12.

In the formation of the panel portions PP, first, the circuit layer 11 and the organic insulating layer 12 are formed on the substrate 10 of the mother substrate MB. Next, as shown in FIG. 13A, the lower electrodes LE1, LE2, and LE3 are formed on the organic insulating layer 12 in the display area DA. Further, the conductive layer CL is formed on the organic insulating layer 12 in the surrounding area SA. Thereafter, the rib layer 5 covering the lower electrodes LE1, LE2, and LE3 and the conductive layer CL are formed in the entire mother substrate MB. At this time, the pixel apertures AP1, AP2, and AP3 are not provided in the rib layer 5. The rib layer 5 can be formed by chemical vapor deposition (CVD).

After the formation of the rib layer 5, a process for forming the partition 6 and the surrounding partition 7 is performed. In this process, layers to be processed into the bottom layers 63 and 73, layers to be processed into the stem layers 64 and 74, and layers to be processed into the top layers 62 and 72 are sequentially formed. Thereafter, a resist patterned in a shape of the partition 6 and the surrounding partition 7 is provided. Each of the above layers is patterned using this resist as a mask. Thus, as shown in FIG. 13B, the partition 6 and the surrounding partition 7 are formed.

Next, the process for providing the pixel apertures AP1, AP2, and AP3 is performed. In this process, a resist covering the partition 6 and the surrounding partition 7 is formed. The rib layer 5 is patterned using this resist as a mask. As shown in FIG. 13B, this process forms the pixel apertures AP1, AP2, and AP3 in the rib layer 5. The respective lower electrodes LE1, LE2, and LE3 are exposed from the pixel apertures AP1, AP2, and AP3. The process of forming the partition 6 and the surrounding partition 7 may be performed after the process of forming the pixel apertures AP1, AP2, and AP3 in the rib layer 5.

Next, the process for forming the display element DE1 is performed. As shown in FIG. 13C, in the formation of the display element DE1, the stacked film FL1 and the sealing layer SE11 are formed across the display area DA and the surrounding area SA first. More specifically, the organic layer OR1, the upper electrode UE1 covering the organic layer OR1, the cap layer CP1 covering the upper electrode UE1, and the sealing layer SE11 covering the cap layer CP1 are formed in this order. The organic layer OR1 covers the lower electrodes LE1, LE2, and LE3 through the pixel apertures AP1, AP2, and AP3 in the display area DA, and covers the rib layer 5 in the display area DA and the surrounding area SA.

The partition 6 and the surrounding partition 7 each having an overhang shape divide the stacked film FL1 into a plurality of parts. The sealing layer SE11 covers each of the divided parts of the stacked film FL1 and the partition 6 and the surrounding partition 7.

For example, the organic layer OR1, the upper electrode UE1, and the cap layer CP1 may be formed by vapor deposition. For example, the sealing layer SE11 may be formed by CVD.

Next, the process for performing the surface treatment on the second surface S2 of the sealing layer SE11 is performed. As shown in FIG. 13D, a plasma treatment is performed on the second surface S2 using a plasma treatment device 100 in this process. As shown in FIG. 13E, this process forms fine uneven parts on the second surface S2, roughening the second surface S2. Thus, the surface roughness of the second surface S2 is greater than that of the first surface S1.

For example, the plasma CVD or the plasma dry etching may be applied for the plasma treatment. When the plasma CVD is adopted, the plasma CVD can be performed in the CVD device in which the formation of the sealing layer SE11 shown in FIG. 13C is performed. When the plasma dry etching is adopted, the plasma dry etching can be performed within the etching device for patterning the stacked film FL1 and the sealing layer SE11 as described later with reference to FIG. 13F and FIG. 13G.

For example, gases used in the plasma CVD include argon (Ar) or nitrogen trifluoride (NF3). For example, gases used in the plasma dry etching include argon, sulfur hexafluoride (SF6), or carbon tetrafluoride (CF4).

The surface treatment for roughening the second surface S2 is not limited to the plasma treatment.

Subsequently, the stacked film FL1 and the sealing layer SE11 are patterned. As shown in FIG. 13F, a resist R1 is provided on the sealing layer SE11 in this patterning. The resist R1 covers the pixel aperture AP1 and a part of the partition 6 around the pixel aperture AP1.

Thereafter, the etching process using the resist R1 as a mask is performed. As shown in FIG. 13G, this process removes parts exposed from the resist R1 of the stacked film FL1 and the sealing layer SE11. That is, the parts overlapping the lower electrode LE1 of the stacked film FL1 and the sealing layer SE11 remain, and the other portions are removed. Thus, the display element DE1 is formed in the subpixel SP1. This etching process may include wet etching and dry etching performed in order for the sealing layer SE11, the cap layer CP1, the upper electrode UE1, and the organic layer OR1. After these etching processes, the resist R1 is removed (stripped).

The stacked film FL1 located under the sealing layer SE11 on the partition 6 is also removed in wet etching for the stacked film FL1. This process forms a gap between the sealing layer SE11 located above the partition 6 and the partition 6. The stacked film FL1 constituting the display element DE1 is completely surrounded by the sealing layer SE11 and the partition 6. Thus, this stacked film FL1 is not corroded by the wet etching.

Next, the process for forming the display element DE2 is performed. The display element DE2 can be formed by the same procedure as that of the display element DE1. That is, in the formation of the display element DE2, the stacked film FL2 and the sealing layer SE12 are formed. The stacked film FL2 includes the organic layer OR2 covering the lower electrode LE2 through the pixel aperture AP2, the upper electrode UE2 covering the organic layer OR2, and the cap layer CP2 covering the upper electrode UE2 as shown in FIG. 3.

The organic layer OR2, the upper electrode UE2, and the cap layer CP2 may be formed by, for example, vapor deposition. The sealing layer SE12 may be formed by, for example, CVD. The partition 6 and the surrounding partition 7 each having an overhang shape divide the stacked film FL2 into a plurality of parts. The sealing layer SE12 covers each of the divided parts of the stacked film FL2 and the partition 6 and the surrounding partition 7. Next, the process for performing the plasma treatment on the second surface S2 of the sealing layer SE12 is performed. This process roughens the second surface S2 of the sealing layer SE12, making the surface roughness of the second surface S2 greater than that of the first surface S1. As shown in FIG. 13H, patterning these stacked film FL2 and sealing layer SE12 forms the display element DE2 in the subpixel SP2.

Next, the process for forming the display element DE3 is performed. The display element DE3 can be formed by the same procedures as those of the display elements DE1 and DE2. That is, in the formation of the display element DE3, the stacked film FL3 and the sealing layer SE13 are formed. As shown in FIG. 3, the stacked film FL3 includes the organic layer OR3 covering the lower electrode LE3 through the pixel aperture AP3, the upper electrode UE3 covering the organic layer OR3, and the cap layer CP3 covering the upper electrode UE3.

The organic layer OR3, the upper electrode UE3, and the cap layer CP3 may be formed by, for example, vapor deposition. The sealing layer SE13 may be formed by, for example, CVD. The partition 6 and the surrounding partition 7 each having an overhang shape divide the stacked film FL3 into a plurality of parts. The sealing layer SE13 covers each of the divided parts of the stacked film FL3 and the partition 6 and the surrounding partition 7. Next, the process for performing the plasma treatment on the second surface S2 of the sealing layer SE13 is performed. This process roughens the second surface S2 of the sealing layer SE13, making the surface roughness of the second surface S2 greater than that of the first surface S1. Patterning these stacked film FL3 and sealing layer SE13 forms the display element DE3 in the subpixel SP3 as shown in FIG. 13I.

Here, the above description assumes that the display elements DE1, DE2, and DE3 are formed in this order. However, the display elements DE1, DE2, and DE3 may be formed in another order.

As shown in FIG. 13J, after the formations of the display elements DE1, DE2, and DE3, the resin layer RS1, the sealing layer SE2, the touch panel electrode TP, the touch panel line TPL, and the resin layer RS2 are formed. The resin layers RS1 and RS2 may be formed by, for example, the ink-jet method. The sealing layer SE2 may be formed by, for example, CVD. Then, each panel portion PP is cut out from the mother substrate MB along the cut line CL1. Further, the panel portion PP is cut along the cut line CL2. This completes the display device DSP.

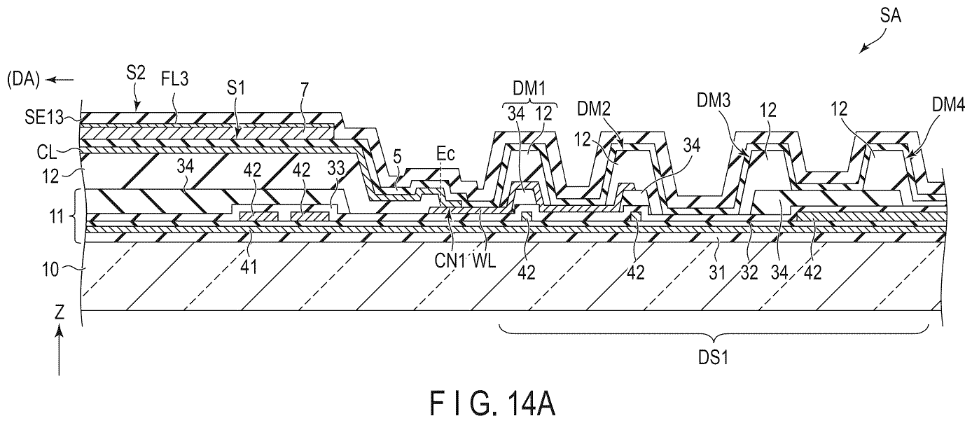

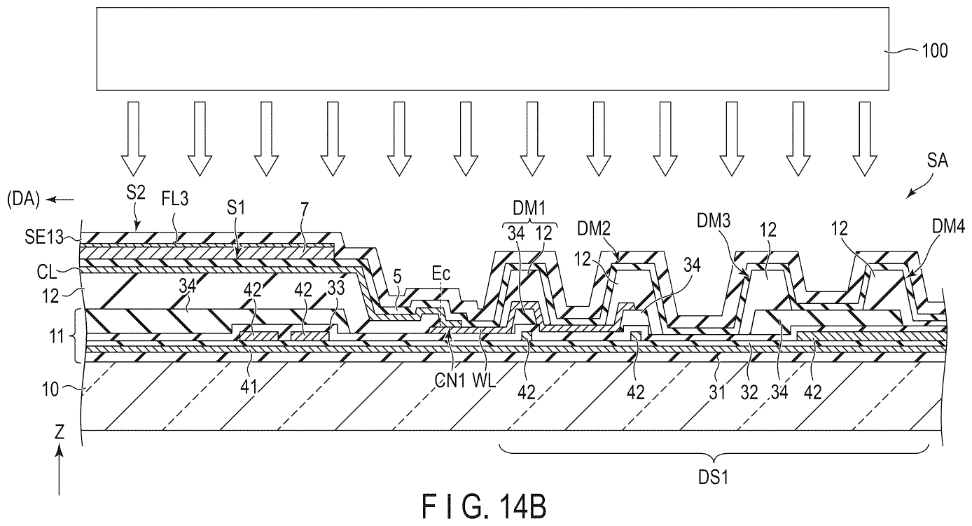

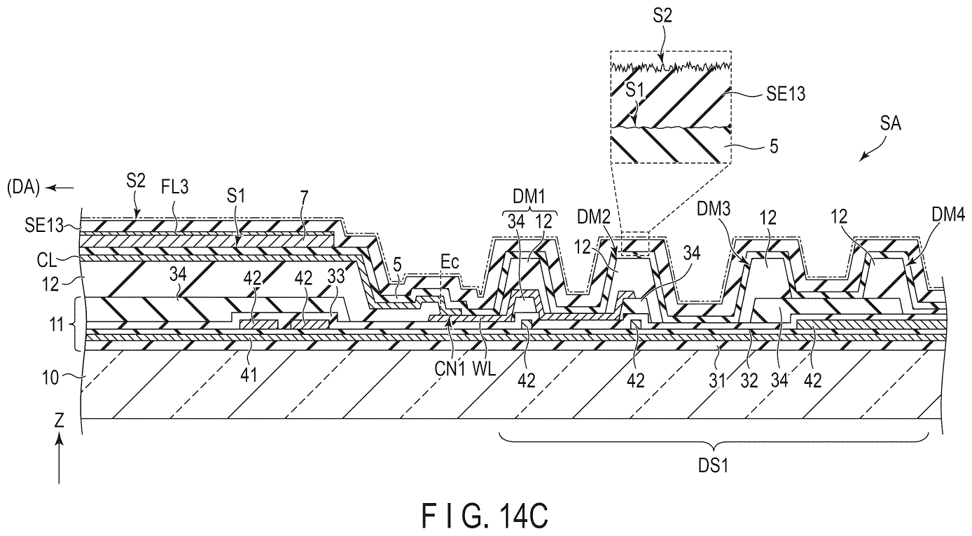

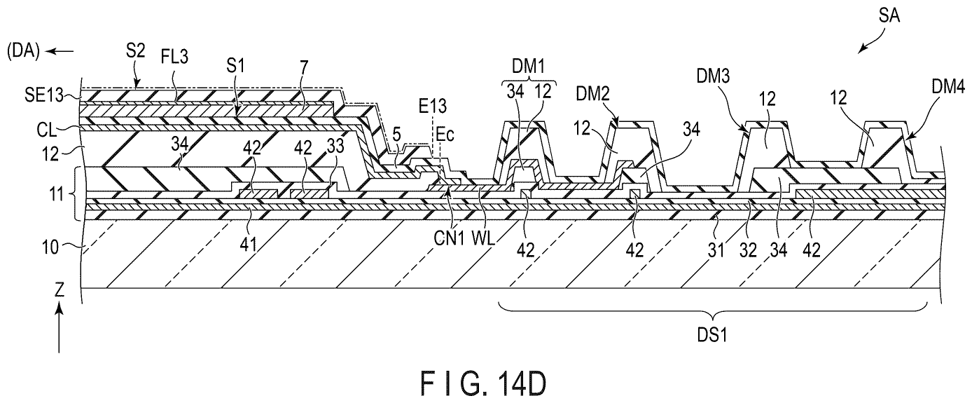

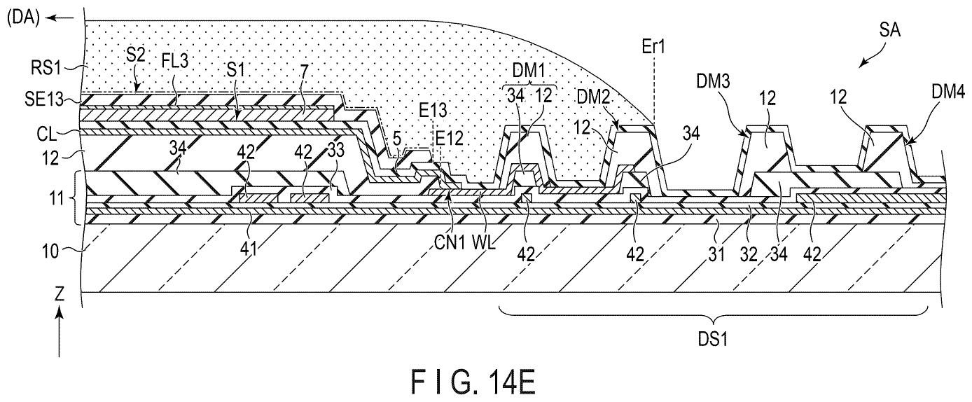

The following will describe an example of the manufacturing method of the display device DSP with focusing on the configuration around the dam portion DS1. FIG. 14A to FIG. 14E are schematic cross-sectional views showing the manufacturing process of the display device DSP.

First, as shown in FIG. 14A, the circuit layer 11, the organic insulating layer 12, the wire WL, the conductive layer CL, the dams DM1, DM2, DM3, and DM4, and the rib layer 5 are formed on the substrate 10. The dams DM1, DM2, DM3, and DM4 are covered with the rib layer 5. The surrounding partition 7 and the stacked film FL3 are formed on the rib layer 5. Further, the sealing layer SE13 covering the rib layer 5, the surrounding partition 7, and the stacked film FL3 is formed. At this time, the sealing layer SE13 covers the dams DM1, DM2, DM3, and DM4.

Next, as shown in FIG. 14B, the process for performing the surface treatment on the second surface S2 of the sealing layer SE13 is performed. This process is performed by the same method as the process shown in FIG. 13D. That is, the plasma treatment is performed on the second surface S2 using the plasma processing device 100. As shown in FIG. 14C, this process forms fine uneven parts on the second surface S2, roughening the second surface S2. Thus, the surface roughness of the second surface S2 is greater than that of the first surface S1.

Next, the etching process for patterning the sealing layer SE13 is performed. As shown in FIG. 14D, this etching removes parts of the dams DM1, DM2, DM3, and DM4 of the sealing layer SE13. This process makes the dam portion DS1 exposed from the sealing layer SE13. After the etching process as well, the surrounding partition 7 is covered with the sealing layer SE13. This etching process is the same as the etching process for patterning the stacked film FL3 and the sealing layer SE13 in the display area DA to form the display element DE3.

Next, as shown in FIG. 14E, the resin layer RS1 is formed. The resin layer RS1 is formed by applying a liquid resin material onto the area inside the dam portion DS1 and curing it. The resin layer RS1 before curing is dammed up by the dam portion DS1. In the example shown in FIG. 14E, the resin layer RS1 before curing is dammed up by the dam DM2.

Next, the sealing layer SE2, the touch panel line TPL, and the resin layer RS2 are formed. Thereafter, each panel portion PP is cut along the cut lines CL1 and CL2. This completes the display device DSP shown in FIG. 10.

The following will describe cases where the surface treatment is not performed on the second surface S2 of each of the sealing layers SE11, SE12, and SE13.

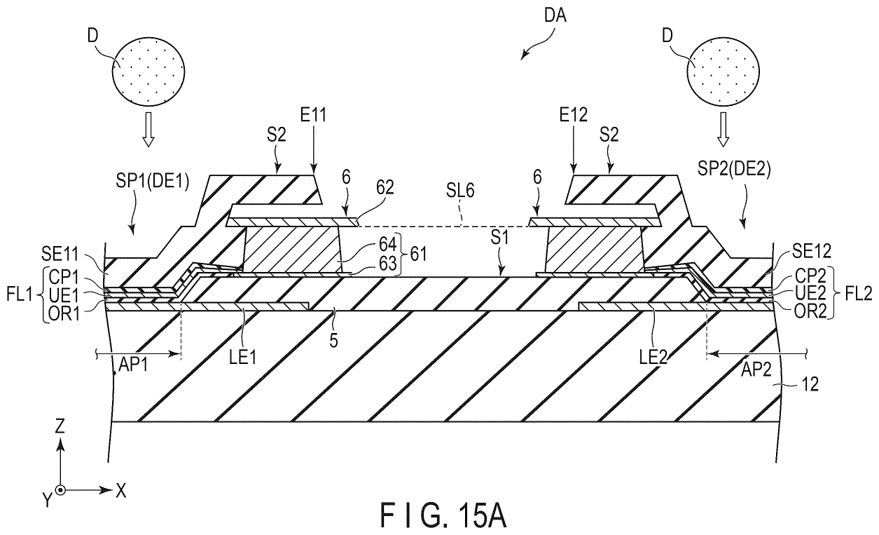

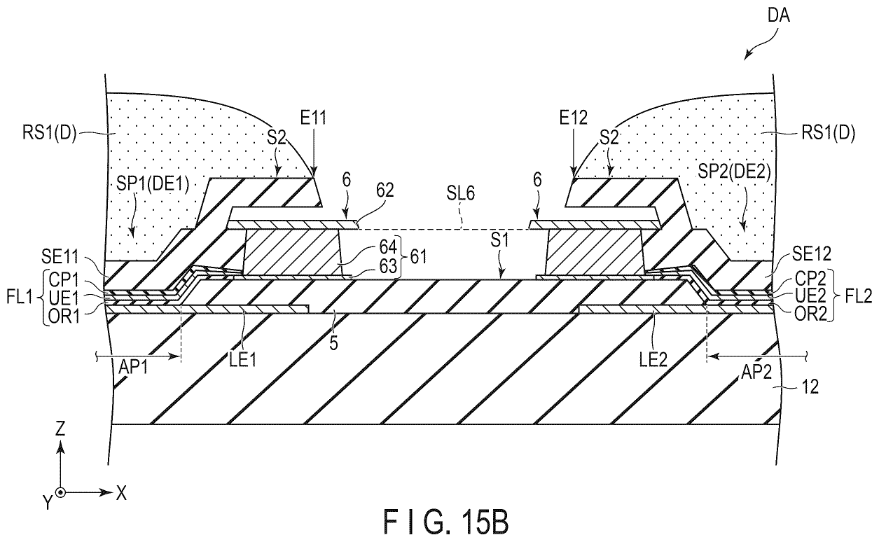

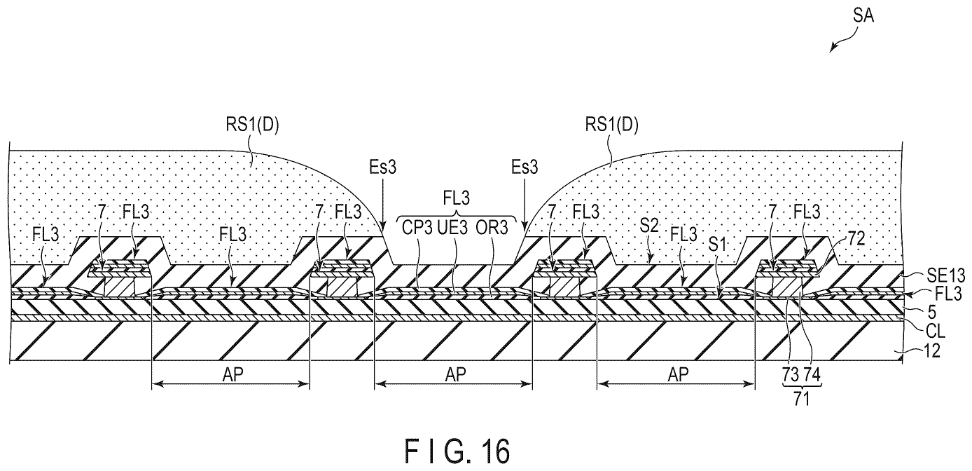

FIG. 15A, FIG. 15B, and FIG. 16 are schematic cross-sectional views showing manufacturing processes of the display device DSP according to a comparative example. In the same manner as FIG. 6, FIG. 15A and FIG. 15B show the configuration around the slits SL6. In this comparative example, the surface treatment is not performed on the sealing layers SE11, SE12, and SE13. Thus, the surface roughness of the second surface S2 is substantially equivalent to that of the first surface S1.

As shown in FIG. 15A, in cases where the resin layer RS1 is formed, for example, by the ink-jet method, droplets D of resin materials are discharged to each of the panel portions PP. Many of these droplets D adhere to the sealing layers SE11, SE12, and SE13.

The droplets D having adhered to the sealing layers SE11, SE12, and SE13 spread as shown in FIG. 15B. Spreading droplets D are repelled by the surface tension at end portions E11 and E12 of the sealing layers SE11 and SE12. Thus, the droplets D may not flow into the slits SL6.

If the droplets D are cured without flowing into the slits SL6, the resin layer RS1 may deform in the vicinity of the slits SL6. If the sealing layer SE2 is formed in this state, the sealing layer SE2 may be broken, potentially forming a moisture intrusion path. Furthermore, the touch panel electrode TP formed on the sealing layer SE2 may break.

In the same manner as FIG. 9, FIG. 16 shows the configuration around the aperture AP of the surrounding partition 7 provided in the surrounding area SA. As shown in FIG. 16, the droplets D having adhered to the second surface S2 of the sealing layer SE13 are repelled by the surface tension at an end portion Es3 of the sealing layer SE13 located above the aperture AP. Thus, the droplets D do not flow into the aperture AP. Thus, the resin layer RS1 may deform. Even in such cases, a moisture intrusion path may be formed due to the separation of the sealing layer SE2 or touch panel wiring TPL may break.

In contrast, the surface treatment is performed on the second surface S2 of each of the sealing layers SE11, SE12, and SE13 in the present embodiment. Thus, the surface roughness is increased. That is, performing the surface treatment on the second surface S2 improves its wettability, making droplets D spread more readily. Thus, the droplets D readily flow into the slits SL6 and the aperture AP. Thus, the resin layer RS1 is smoothed, and thus the resin layer RS1 with a flat upper surface can be formed. This configuration suppresses the separation of the sealing layer SE2 and the breakage of the touch panel electrode TP and the touch panel line TPL. Thus, the configuration can improve the yield of the display device DSP.

This surface treatment (the plasma treatment) can be performed within the device used for the process preceding or following the process where the surface treatment is performed. More specifically, the surface treatment can be performed using the CVD device for forming the sealing layers SE11, SE12, and SE13 or the etching device for forming the display elements DE1, DE2, and DE3. Thus, an additional device for the surface treatment is unnecessary. This leads to the omission of the manufacturing processes and the reduction of investment in plant and equipment.

In the present embodiment, the end portion E13 of the sealing layer SE13 is located between the surrounding partition 7 and the dam DM1. That is, the dams DM1, DM2, DM3, and DM4 are not covered with the sealing layer SE13. Thus, wettability only in the areas where the sealing layers SE11, SE12, and SE13 are formed can be increased without altering the wettability of the area around the dam portion DS1. This facilitates position control of the end portion Er1 of the resin layer RS1, allowing the width of each of the dams DM1, DM2, DM3, and DM4 to be narrowed or the number of the dams to be reduced. Thus, the display device DSP with narrower bezels can be obtained.

Furthermore, the end portion E13 is located between the surrounding partition 7 and the dam DM1. Thus, the sealing layers SE13 and SE2 do not contact each other in the area outside the end portion Er1 of the resin layer RS1. If the sealing layer SE13 and the sealing layer SE2 were to contact each other, the uneven shape of the second surface S2 could be reflected onto the upper surface of the sealing layer SE2, potentially forming unintended uneven parts on the upper surface of the sealing layer SE2. The uneven parts formed on the upper surface of the sealing layer SE2 could cause the area where the sealing layer SE13 and the sealing layer SE2 contact to appear cloudy, potentially hindering visual inspection.

In contrast, in the present embodiment, the sealing layer SE2 contacts the rib layer 5 in the area outside the end portion Er1 of the resin layer RS1. Thus, the cloudiness does not occur, and thus yield deterioration can be suppressed. Furthermore, the resin layer RS1 is thicker than the sealing layer SE2. Thus, almost no uneven parts caused by the uneven shape of the second surface S2 are formed on the upper surface of the resin layer RS1.

All of the display devices and the manufacturing methods of the display devices that can be implemented by a person of ordinary skill in the art through arbitrary design changes to the display device and the manufacturing method of the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a substrate having a display area for displaying images and a surrounding area outside the display area;
a first lower electrode provided above the substrate in the display area;
a rib layer formed of an inorganic material and including a first surface located on a side opposite to the substrate and a pixel aperture overlapping the first lower electrode;
a partition having a first lower portion provided on the first surface and having conductivity and a first upper portion provided on the first lower portion and protruding relative to a side surface of the first lower portion;
an organic layer contacting the first lower electrode through the pixel aperture;
an upper electrode covering the organic layer and contacting the first lower portion;
a cap layer covering the upper electrode; and
a first sealing layer formed of an inorganic material, covering the cap layer, and having a second surface located on a side opposite to the substrate and having a surface roughness greater that of the first surface.

2. The display device of claim 1, further comprising:
a dam portion provided in the surrounding area, surrounding the display area, and covered with the rib layer, wherein
the first sealing layer has an end portion located between the display area and the dam portion in plan view.

3. The display device of claim 2, further comprising:
a first resin layer covering the second surface and formed of an organic material, wherein
the first resin layer covers at least part of the dam portion.

4. The display device of claim 1, further comprising:
a surrounding partition provided on the rib layer in the surrounding area and surrounding the display area, wherein
the first sealing layer covers the surrounding partition.

5. The display device of claim 4, wherein
the surrounding partition has a plurality of apertures, and
the first sealing layer covers the plurality of apertures.

6. The display device of claim 5, wherein
the first sealing layer contacts the cap layer through the aperture.

7. The display device of claim 4, further comprising:
a dam portion provided in the surrounding area, surrounding the display area and the surrounding partition, and covered with the rib layer, wherein
the first sealing layer has an end portion located between the surrounding partition and the dam portion.

8. The display device of claim 4, wherein
the surrounding partition has a second lower portion provided on the first surface and a second upper portion provided on the second lower portion and protruding relative to a side surface of the second lower portion.

9. The display device of claim 1, further comprising:
a second lower electrode provided in the display area and spaced apart from the first lower electrode in a first direction, wherein
the partition has a slit provided between the first lower electrode and the second lower electrode and extending in a second direction intersecting the first direction.

10. The display device of claim 9, wherein
the first sealing layer has a first portion provided directly above the first lower electrode and a second portion provided directly above the second lower electrode, and
the first portion and the second portion are spaced apart from each other directly above the slit.

11. The display device of claim 9, further comprising:
a first resin layer covering the second surface and formed of an organic material, and
the first resin layer contacts the rib layer in the slit.

12. The display device of claim 1, further comprising:
a first resin layer covering the second surface and formed of an organic material;
a second sealing layer covering the first resin layer and formed of an inorganic material; and
a second resin layer covering the second sealing layer and formed of an organic material.

13. A manufacturing method of a display device, the method comprising steps of:
forming a lower electrode in a display area for displaying images;
forming a rib layer having a pixel aperture overlapping the lower electrode and formed of an inorganic material and a partition having a first lower portion provided on the rib layer and having conductivity and a first upper portion provided on the first lower portion and protruding relative to a side surface of the first lower portion;
forming across the display area and a surrounding area outside the display area an organic layer contacting the lower electrode through the pixel aperture, an upper electrode covering the organic layer and contacting the first lower portion, a cap layer covering the upper electrode, and a first sealing layer covering the cap layer; and
performing a surface treatment on an upper surface of the first sealing layer to roughen the upper surface.

14. The manufacturing method of claim 13, wherein
the surface treatment is a plasma treatment.

15. The manufacturing method of claim 14, wherein
the plasma treatment is a plasma CVD or a plasma dry etching.

16. The manufacturing method of claim 14, wherein
gas used in the plasma treatment includes any of argon, nitrogen trifluoride, sulfur hexafluoride, or carbon tetrafluoride.

17. The manufacturing method of claim 13, further comprising a step of:
after the surface treatment, forming a display element by forming a resist covering the pixel aperture on the first sealing layer and performing etching to remove parts exposed from the resist of the organic layer, the upper electrode, the cap layer, and the first sealing layer.

18. The manufacturing method of claim 13, further comprising steps of:
before forming the rib layer, forming a dam portion surrounding the display area in the surrounding area;
forming the rib layer covering the dam portion in the step of forming the rib layer;
forming the first sealing layer covering the dam portion on the rib layer in the process of forming the first sealing layer; and
after the surface treatment, removing the first sealing layer covering the dam portion.

19. The manufacturing method of claim 18, further comprising a step of:
after removing the first sealing layer covering the dam portion, forming a first resin layer on the first sealing layer, an end portion of the first resin layer being dammed up by the dam portion.

20. The manufacturing method of claim 18, further comprising steps of:
at the same time of the process of forming the partition, forming a surrounding partition surrounding the display area and having a second lower portion provided on the rib layer and a second upper portion provided on the second lower portion and protruding relative to a side surface of the second lower portion in the surrounding area, wherein
after the step of removing the first sealing layer covering the dam portion, the first sealing layer covers the surrounding partition.
